(19) United States
(12) Patent Application Publication
(10) Pub. No.: US 2009/0087989 A1
(43) Pub. Date: Apr. 2, 2009

(54) POLISHING LIQUID AND POLISHING METHOD USING THE SAME

(75) Inventor: Tetsuya Kamimura, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/236,965

(22) Filed: Sep. 24, 2008

(30) Foreign Application Priority Data
Sep. 28, 2007 (JP) 2007-255969

(51) Int. Cl. C09K 13/00; H01L 21/302

(52) U.S. Cl. 438/693; 252/79.1; 257/E21.304

(57) ABSTRACT

The invention provides a polishing liquid used for chemical mechanical polishing during planarization of a semiconductor integrated circuit, having at least: a benzotriazole compound (A) represented by the following Formula (1); an acid (B); and a water-soluble polymer (C). The invention further provides a polishing method for planarizing a semiconductor integrated circuit, the polishing method includes at least essentially chemically and mechanically polishing a barrier layer of the semiconductor integrated circuit using the polishing liquid.

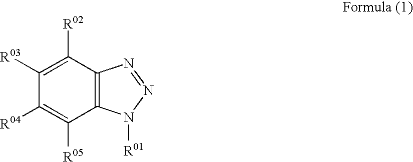

In Formula (1), each of R⁰¹ to R⁰⁵ independently represents a hydrogen atom or an alkyl group, and at least one of R⁰¹ to R⁰⁵ represents an alkyl group.

### CROSS-REFERENCE TO RELATED APPLICATION

This application claims priority under 35 USC 119 from Japanese patent Application No. 2007-255969 filed Sep. 28, 2007, the disclosure of which is incorporated by reference herein.

### BACKGROUND OF THE INVENTION

1. Field of the Invention

The present invention relates to a polishing liquid which can be used for producing a semiconductor device and a polishing method using the polishing liquid. More specifically, the invention relates to a polishing liquid which can be used for chemical mechanical polishing for planarizing in a wiring process of a semiconductor device and a polishing method using the polishing liquid.

2. Related art

In recent years, in the development of semiconductor devices such as semiconductor integrated circuits (hereinafter referred to as LSI), increases in density and integration level by making wirings finer and layering more wiring layers have been demanded for the purposes of downsizing and enhancing the processing speed of the devices. Various techniques such as chemical mechanical polishing (hereinafter referred to as CMP) have been employed for such purposes. CMP is an essential technique for processes such as surface planarization of a film to be processed such as an interlayer insulating film, formation of plugs, formation of buried metal lines or the like. CMP is used for smoothing substrates, and removing excessive portions of metal thin films and barrier layers unnecessary for wiring formation.

Common CMP methods include attaching a polishing pad to a circular polishing platen, impregnating the surface of the polishing pad with a polishing liquid, pressing the surface of the substrate (wafer) against the polishing pad, and rotating the polishing platen and the substrate while applying a predetermined pressure (polishing pressure) from the backside of the substrate so that the substrate surface is planarized by the mechanical friction generated therebetween.

In the manufacture of semiconductor devices such as LSI, fine wiring is formed in layers. When Cu or other metal wiring is formed in respective layers, a barrier metal layer composed of Ta, TaN, Ti, TiN or the like is formed in advance to prevent diffusion of a wiring material into the interlayer insulating film and to improve the adhesiveness of the wiring material to a substrate.

Methods for forming wiring layers generally include performing single-stage or multistage CMP of the metal film (hereinafter referred to as “metal film CMP”) to remove excessive portions of the wiring material deposited by plating or the like, and then removing the exposed portions of the barrier metal material (barrier metal layer) by CMP (hereinafter referred to as “barrier metal CMP”). However, metal film CMP may cause dishing, in which wiring portions are excessively polished, and may further cause erosion.

In order to reduce the extent of the dishing, the polishing rates at the metal wiring portion and the barrier metal portion are adjusted in the barrier metal CMP which follows the metal film CMP so as to form a wiring layer containing a minimum of level differences caused by dishing or erosion. More specifically, in the barrier metal CMP, if the polishing rates for the barrier metal and the interlayer insulating film are relatively lower than that for the metal wiring material, the wiring portion is more rapidly polished, which results in dishing and, in turn, erosion. Therefore, it is preferable that the polishing rates for the barrier metal and the insulating film layer are adequately high. This improves the throughput of the barrier metal CMP and since, in practice, the metal film CMP often causes dishing, it is desirable to relatively increase the polishing rates for the barrier metal and the interlayer insulating film for this reason in addition to the above reason.

The metal polishing liquid used for CMP usually contains abrasive grains such as those formed of alumina or silica, and an oxidant such as hydrogen peroxide or persulfuric acid. The basic mechanism of CMP is thought to be such that the oxidant oxidizes a surface of a metal being polished, and the resultant oxidized film is removed by the abrasive grains, whereby the surface is polished.

However, CMP using such a polishing liquid containing solid abrasive grains may cause polishing flaws (scratches), excessive polishing of the surface (thinning), a phenomenon in which a portion of a polished metal surface is indented because of excessive polishing (dishing), and a phenomenon in which excessive polishing of insulators between metal wirings accompanied by deep polishing only of central portions of multiple wired metal surfaces results in indentation of the surface (erosion).

In addition, the use of a polishing liquid containing solid abrasive grains may not be cost-effective because a washing step, which is usually conducted after polishing in order to remove the polishing liquid remaining on the semiconductor surface, is complicated and, further, it is necessary to remove the solid abrasive grains from the wash water by sedimentation.

The following kinds of various studies have been conducted on polishing liquid containing solid abrasive grains.

For example, Japanese Patent Application Laid-Open (JP-A) No. 2003-17446 proposes a CMP abrasive compound and a polishing process for high-speed polishing with little generation of polishing flaws; JP-A No. 2003-142435 proposes a polishing composition and a polishing process which provide improved washability in CMP; and JP-A No. 2000-84832 proposes a polishing composition which is intended to prevent aggregation of abrasive grains.

However, even these kinds of polishing liquids have not yet provided a technique that enables polishing of a target layer (barrier layer) at a high rate as well as suppression of scratches caused by aggregation of solid abrasive grains.

Specifically, in recent years, low dielectric constant materials having a lower relative dielectric constant than common interlayer insulating films such as TEOS have been used as insulating films along with the further refinement of wiring. Such insulating films, which are referred to as Low-k films, are composed of organic polymer, SiOC or SiOF materials or the like, and are usually layered with a wiring layer. Since such insulating films have lower strength than conventionally-known insulating films, they are highly susceptible to excessive polishing or scratches during CMP.

### SUMMARY

The present invention provides a polishing liquid used for chemical mechanical polishing performed in the planarization of semiconductor integrated circuits, the polishing liquid containing substantially no solid abrasive grain. The polishing liquid of the present invention enables polishing of layers formed on semiconductor integrated circuits with a practically workable polishing rate, while suppressing the occurrence of scratches on a polished surface.

Namely, a first aspect of the present invention is a polishing liquid used for chemical mechanical polishing during planarization of a semiconductor integrated circuit, the polishing liquid being substantially free of solid abrasive grains and comprising: a benzotriazole compound (A) represented by the following Formula (1); an acid (B); and a water-soluble polymer (C).

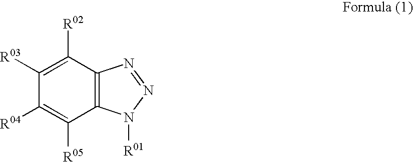

In Formula (1), each of R⁰¹ to R⁰⁵ independently represents a hydrogen atom or an alkyl group, and at least one of R⁰¹ to R⁰⁵ represents an alkyl group.

A second aspect of the present invention is a polishing method for planarizing a semiconductor integrated circuit, the polishing method comprising chemically and essentially mechanically polishing a barrier layer of the semiconductor integrated circuit using the polishing liquid.

The polishing liquid and the polishing method of the present invention enables polishing of layers formed on semiconductor integrated circuits with a practically workable polishing rate, while remarkably suppressing the occurrence of scratches on a polished surface as comparing to conventional polishing liquids which do not have the configuration of the polishing liquid or the polishing method of the present invention.

### DETAILED DESCRIPTION OF THE INVENTION

The polishing liquid of the invention contains substantially no solid abrasive grain which is usually used for chemical mechanical polishing during planarization of a semiconductor integrated circuit, and contains at least: a benzotriazole compound (A) represented by Formula (1) (hereinafter may be referred to as “the benzotriazole compound according to the invention”); an acid (B); and a water-soluble polymer (C). The polishing liquid may further contain, as necessary, additionally-used components. The components of the polishing liquid of the invention may be used singly or in combination of two or more thereof.

The scope of the “polishing liquid” herein includes a polishing liquid used for polishing (more specifically, a polishing liquid which may be diluted as necessary) as well as a concentrated polishing liquid.

A “concentrate”, a “concentrated liquid” and a “concentrated polishing liquid” respectively refer to a polishing liquid containing the solute at a higher ratio than the polishing liquid actually used for polishing. The concentrated liquid and the concentrated polishing liquid are diluted with water or an aqueous solution before being applied for polishing. The dilution ratio is usually 1 to 20 times by volume. In the present description, the term “concentrated” means that “thicker than the concentration at application”, and the term “concentrated liquid” means “a thicker solution than the concentration at application”. The means of these terms used herein are differentiated from common means of “concentrate”, which involves physical concentrating operations such as evaporation.

The components of the polishing liquid of the invention are further described below in detail.

Benzotriazole compound (A) represented by Formula (1)

The benzotriazole compound according to the invention is a benzotriazole compound represented by Formula (1), and has one or more alkyl groups as substituents. The benzotriazole compound according to the invention is a so-called corrosion inhibitor which is adsorbed to a polished surface and forms a film thereon so as to suppress corrosion of a metal surface.

The benzotriazole compound according to the invention has at least one alkyl group. The posession of the at least one alkyl group likely sufficiently suppress corrosion of metal wiring, and the metal wiring suppresses excessive polishing of the insulating layer.

When the benzotriazole compound according to the invention is used without being combined with abrasive grains such as colloidal silica, it achieves a remarkable effect in preventing scratches. The reason thereof is estimated to be that excessive cutting force associated with known polishing particles is not exerted in this system, while the invention is not limited by the estimation.

In order to obtain sufficient effect of suppressing corrosion of wiring, the loading amount of the benzotriazole compound according to the invention is preferably in a range of 0.0001% by mass to 1% by mass, and is more preferably in a range of 0.001% by mass to 0.5% by mass, with respect to the total amount of the polishing liquid used for polishing.

The benzotriazole compound according to the invention is a benzotriazole compound represented by Formula (1), a substituent of which is exclusively one or more alkyl groups.

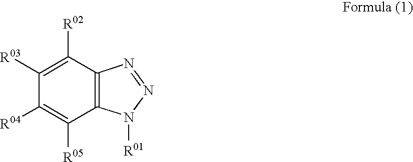

In Formula (1), each of R⁰¹ to R⁰⁵ independently represents a hydrogen atom or an alkyl group, and at least one of R⁰¹ to R⁰⁵ is an alkyl group.

The alkyl groups represented by R⁰¹ to R⁰⁵ may be respectively linear, branched, or cyclic, and are respectively preferably an linear alkyl group. The alkyl groups represented by R⁰¹ to R⁰⁵ are preferably alkyl groups having 1 to 10 carbon atoms, more preferably alkyl groups having 1 to 5 carbon atoms, and even more preferably alkyl groups having 1 to 3 carbon atoms.

The alkyl groups represented by R⁰¹ to R⁰⁵ may have a substituent. Examples of the substituent include a halogen atom (a fluorine atom, a chlorine atom, a bromine atom, or an iodine atom), an alkyl group (a linear, branched or cyclic alkyl group, which may be a polycyclic alkyl group such as a bicycloalkyl group, and may include an active methine group), an alkenyl group, an alkynyl group, an aryl group, a heterocyclic group (the site of substitution is arbitrary), an acyl group, an alkoxycarbonyl group, an aryloxycarbonyl group, a heterocyclic oxycarbonyl group, a carbamoyl group (examples of the substituted carbamoyl group include an N-hydroxycarbamoyl group, an N-acylcarbamoyl group, an N-sulfonylcarbamoyl group, an N-carbamoylcarbamoyl group, a thiocarbamoyl group, and an N-sulfamoylcarbamoyl group), a carbazoyl group, a carboxy group or salts thereof, an oxalyl group, an oxamoyl group, a cyano group, a carbonimidoyl group, a formyl group, a hydroxy group, an alkoxy group (including a group containing repeated units of an ethyleneoxy group or a propyleneoxy group), an aryloxy group, a heterocyclic oxy group, an acyloxy group, an (alkoxy or aryloxy)carbonyloxy group, a carbamoyloxy group, a sulfonyloxy group, an amino group, an (alkyl, aryl, or heterocyclic)amino group, an acylamino group, a sulfonamide group, an ureido group, a thioureido group, an N-hydroxyureido group, an imide group, an (alkoxy or aryloxy)carbonylamino group, a sulfamoylamino group, a semicarbazide group, a thiosemicarbazide group, a hydrazino group, an ammonio group, an oxamoylamino group, an N-(alkyl or aryl)sulfonylureido group, an N-acylureido group, an N-acylsulfamoylamino group, a hydroxyamino group, a nitro group, a heterocyclic group containing a quaternary nitrogen atom (such as a pyridinio group, an imidazolio group, a quinolinio group, or an isoquinolinio group), an isocyano group, an imino group, a mercapto group, an (alkyl, aryl, or heterocyclic)thio group, an (alkyl, aryl, or heterocyclic)dithio group, an (alkyl or aryl)sulfonyl group, an (alkyl or aryl)sulfinyl group, a sulfo group, a sulfamoyl group (examples of the substituted sulfamoyl group include an N-acylsulfamoyl group, and an N-sulfonylsulfamoyl group), a phosphino group, a phosphinyl group, a phosphinyloxy group, a phosphinylamino group, and a silyl group. Among them, examples which are preferable from the viewpoint of effectively inhibiting corrosion of metal wiring include nonsubstituted alkyl groups.

Particularly preferable examples of the alkyl groups represented by R⁰¹ to R⁰⁵ include a methyl group, an ethyl group, a propyl group, a butyl group, a pentyl group, a hexyl group, and a cyclohexyl group. Among them, more preferable examples include a methyl group, an ethyl group, a propyl group, and a butyl group.

The number of alkyl groups contained in the benzotriazole compound according to the invention is not particularly specified as long as it is 1 or more. The number of alkyl groups is preferably from 1 to 3, and more preferably from 1 to 2.

The site of substitution with the alkyl group in the benzotriazole compound according to the invention is not particularly specified. When the number of alkyl group is three, it is preferable that R⁰¹, R⁰³, and R⁰⁴ are alkyl groups. When the number of alkyl group is 2, it is preferable that R⁰¹ and R⁰³, or R⁰³ and R⁰⁴ are alkyl groups. When the number of alkyl group is 1, it is preferable that R⁰¹ or R⁰³ is an alkyl group.

Specific examples of the benzotriazole compound (A) according to the invention are listed below, while the invention is not limited to them.

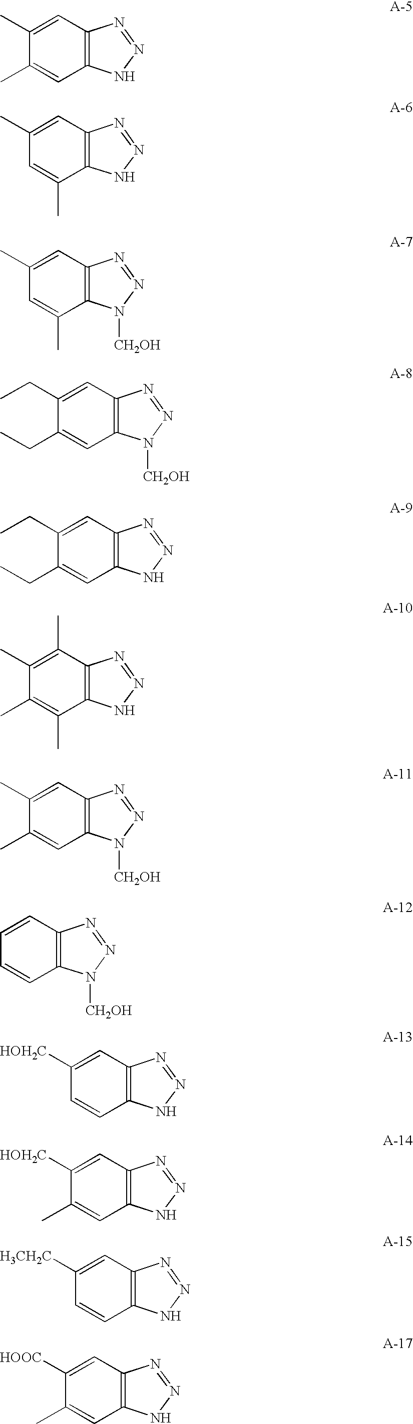

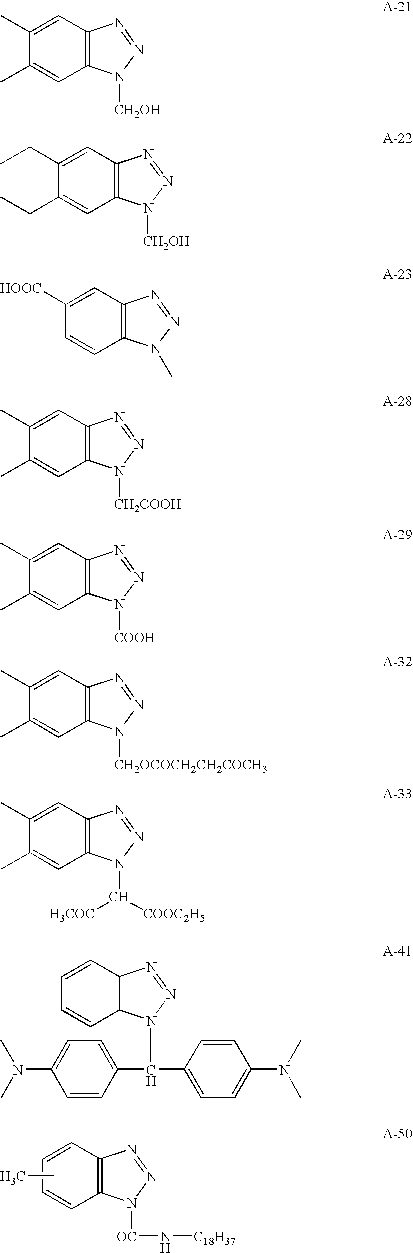

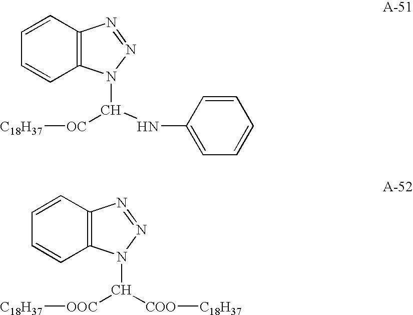

The polishing liquid of the invention may additionally contain other azole compound besides the benzotriazole compound according to the invention.

The amount of the benzotriazole of the invention with respect to the total amount of azoles contained in the polishing liquid used for polishing (namely, the content of the benzotriazole of the invention) is preferably from 50% to 100% by mass, more preferably from 60% to 100% by mass, and even more preferably from 80% to 100% by mass.

Examples of the additionally-contained azole compound include unsubstituted benzotriazole, benzotriazole compounds such as aminobenzotriazole, alkoxybenzotriazole, tolyltriazole, 1-(1,2-dicarboxyethyl)tolyltriazole, or 1-[N,N-bis(hydroxyethyl)aminomethyl]tolyltriazole, and known corrosion inhibitors having mother nucleus which are largely different from that of benzotriazole, such as imidazole, 1,2,3-triazole, 1,2,4-triazole, or tetrazole, and modified compounds thereof. Among them, preferable examples include unsubstituted benzotriazole, aminobenzotriazole, alkoxybenzotriazole, 1,2,3-triazole, 1,2,4-triazole, and tetrazole.

Acid (B)

The polishing liquid of the invention contains an acid. The acid accelerates oxidation, adjusts the pH, and serves as a buffering agent. The acid may be either an organic acid or an inorganic acid. The acid of polishing liquid of the invention preferably contains an organic acid.

Preferable examples of the organic acid include formic acid, acetic acid, propionic acid, butyric acid, valeric acid, 2-methylbutyric acid, N-hexanoic acid, 3,3-dimethylbutyric acid, 2-ethylbutyric acid, 4-methylpentanoic acid, N-heptanoic acid, 2-methylhexanoic acid, N-octanoic acid, 2-ethylhexanoic acid, benzoic acid, glycolic acid, salicylic acid, glycolic acid, oxalic acid, malonic acid, succinic acid, glutaric acid, adipic acid, pimelic acid, maleic acid, phthalic acid, malic acid, tartaric acid, citric acid, and lactic acid, and ammonium salts thereof, alkali metal salts thereof, sulfates thereof, and nitrates thereof, and mixtures of any of these.

Among them, more preferable examples include oxalic acid, glycolic acid, lactic acid, malonic acid, succinic acid, glutaric acid, adipic acid, maleic acid, malic acid, tartaric acid, citric acid, and modified compounds thereof from the viewpoint of effectively suppressing erosion while keeping a practical CMP rate.

Preferable examples of the organic acid further include an amino acid and the like.

The amino acid and the like are preferably water-soluble. More preferable examples of the amino acid include glycine, L-alanine, β-alanine, L-2-aminobutyric acid, L-norvaline, L-valine, L-leucine, L-norleucine, L-isoleucine, L-alloisoleucine, L-phenyl alanine, L-prowiringarcosine, L-ornithine, L-lysine, taurine, L-serine, L-threonine, L-allothreonine, L-homoserine, L-tyrosine, 3,5-diiodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteineacid, L-asparatic acid, L-glutamic acid, S-(carboxymethyl)-L-cysteine, 4-aminobutyric acid, L-asparagine, L-glutamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, L-tryptophan, actinomycin Cl, apamin, angiotensin I, angiotensin II, and antipain.

The content of the organic acid in 1 L of the polishing liquid used for polishing is preferably from 0.0005 mol to 0.5 mol, more preferably from 0.005 mol to 0.3 mol, and particularly preferably from 0.01 mol to 0.1 mol. More specifically, the content of the organic acid in 1 L of the polishing liquid may be preferably 0.5 mol or less from the viewpoint of etching inhibition, and may be preferably 0.0005 mol or more from the viewpoint of achieving sufficient effect.

Preferable examples of the inorganic acid include inorganic acids such as nitric acid, sulfuric acid, or phosphoric acid, carbonates such as sodium carbonate, phosphates such as trisodium phosphate, borates, tetraborates, and hydroxybenzoic acid salts. Particularly preferable examples of the inorganic acid include nitric acid.

The content of the inorganic acid in the polishing liquid is not particularly specified as long as the pH is maintained within a preferable range. The content of the inorganic acid in 1 L of the polishing liquid used for polishing is preferably from 0.0001 mol to 1.0 mol, and is more preferably from 0.003 mol to 0.5 mol.

Water-Soluble Polymer (C)

The polishing liquid of the invention may contain a water-soluble polymer as a favorable ingredient.

The water-soluble polymer is preferably a polymer having a carboxylic monomer as a basic structural unit, a salt of such polymer, or a copolymer containing the polymer and/or the salt. Specific examples of the water-soluble polymer include: polyacrylic acid, salts thereof, and copolymers containing these; polymethacrylic acid, salts thereof, and copolymers containing these; polyamide acid, salts thereof, and copolymers containing these; and polycarboxylic acids such as polymaleic acid, polyitaconic acid, polyfumaric acid, poly(p-styrenecarboxylic acid), or polyglyoxalic acid, salts thereof, and copolymers containing these. Other specific examples include vinyl polymers such as polyvinyl alcohol, polyvinyl pyrrolidone, or polyacrolein.

In cases where the object to be polished is a silicon substrate for a semiconductor integrated circuit or the like, it is undesirable that the object is contaminated with an alkali metal, an alkaline earth metal, a halide or the like. Therefore, when the water-soluble polymer is an acid, it is desirable that the water-soluble polymer is used in the original form as the acid or in the form of an ammonium salt thereof.

Among the examples of the water-soluble polymers, more preferable examples of the water-soluble polymer (C) include polyacrylic acid, polymethacrylic acid, polymaleic acid, polyacrylamide, ammonium salts of polyacrylic acid, polyvinyl alcohol, polyvinyl pyrrolidone, polyethylene glycol, copolymers containing these, and polyoxyethylene-polyoxypropylene block polymers, and even more preferable examples thereof include polyacrylic acid, polymethacrylic acid, polymaleic acid, polyacrylamide, and copolymers containing any of these.

Preferable examples of the copolymer include a polyacrylic acid-polymethacrylic acid copolymer and a polyacrylic acid-polyacrylamide copolymer.

The total content of the water-soluble polymer (C) is preferably from 0.001 g to 10 g, more preferably from 0.01 g to 5 g, and is particularly preferably from 0.1 g to 3 g in 1 L of the polishing liquid used for polishing. More specifically, the content of the water-soluble polymer is preferably 0.001 g or more from the viewpoint of achieving sufficient effect, and preferably 10 g or less from the viewpoint of preventing reduction of the CMP rate.

The weight average molecular weight of the water-soluble polymer (C) is preferably from 500 to 100,000, and particularly preferably from 2,000 to 50,000.

In the invention, the water-soluble polymer (C) may be used singly, or in combination of two or more thereof.

Quaternary Ammonium Cation (D)

The polishing liquid of the invention may contain, as a preferable component, a quaternary ammonium cation (D) having one or more quaternary nitrogen atoms in a molecule thereof (hereinafter sometimes referred to as “specific cation” or “quaternary ammonium cation”).

While the behavior of the quaternary ammonium cation is not clear, it is estimated as follows.

The interaction between the polishing particles and the surface to be polished is estimated as being strengthened as a result of adsorption of the quaternary ammonium cation in the polishing liquid to the surfaces of polishing particles. More specifically, it is estimated that the quaternary ammonium cation relieves repulsion between the negatively charged surfaces of the polishing particles and the negatively charged surface to be polished. This is considered to result in enhancement of the physical action between the polishing particles and the surface to be polished (namely, physical action for removing by scratching), and improves the polishing rate for various kinds of films.

The quaternary ammonium cation is not particularly limited as long as it has one or more quaternary nitrogen atoms in a molecule thereof. From the viewpoint of sufficiently improving the polishing rate, the cation preferably has a structure represented by the following Formula (2) or (3).

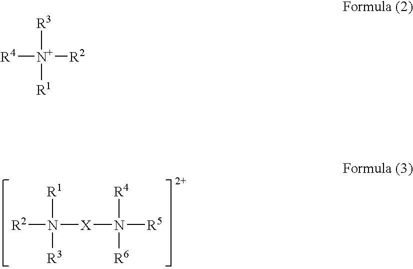

In Formulae (2) and (3), each of R¹ to R⁶ independently represents an alkyl group having 1 to 20 carbon atoms, an alkenyl group, a cycloalkyl group, an aryl group, or an aralkyl group. Two among R¹ to R⁶ may be linked with each other to form a cyclic structure.

Specific examples of the alkyl group having 1 to 20 carbon atoms which is independently represented by each of the R¹ to R⁶ include a methyl group, an ethyl group, a propyl group, a butyl group, a pentyl group, a hexyl group, a heptyl group, and an octyl group. Among them, preferable examples include a methyl group, an ethyl group, a propyl group, and a butyl group.

Preferable examples of the alkenyl group which is independently represented by each of the R¹ to R⁶ include an alkenyl group having 2 to 10 carbon atoms, and specific examples thereof include an ethenyl group and a propenyl group.

Specific examples of the cycloalkyl group which is independently represented by the each of R¹ to R⁶ include a cyclohexyl group and a cyclopentyl group. Among them, preferable examples include a cyclohexyl group.

Specific examples of the aryl group which is independently represented by each of the R¹ to R⁶ include a phenyl group and a naphthyl group. Among them, preferable examples include a phenyl group.

Specific examples of the aralkyl groups which is independently represented by each of the R¹ to R⁶ include a benzyl group and a phenylethyl group. Among them, preferable examples include a benzyl group.

The groups represented by the R¹ to R⁶ may have substituents. Examples of the substituent include a hydroxy group, an amino group, a carboxyl group, a heterocyclic group, a pyridinium group, an aminoalkyl group, a phosphate group, an imino group, a thiol group, a sulfo group, and a nitro group.

In Formula (3), X represents an organic linking group selected from the group consisting of an alkylene group having 1 to 10 carbon atoms, an alkenylene group, a cycloalkylene group, an arylene group, and a combination of two or more of these groups.

The linking group represented by X may contain, in the chain thereof, —S—, —S(═O)₂—, —O—, and/or —C(═O)— in addition to the organic linking group.

Specific examples of the alkylene group having 1 to 10 carbon atoms include a methylene group, an ethylene group, a propylene group, a butylene group, a pentylene group, a hexylene group, a heptylene group, and an octylene group. Among them, preferable examples include an ethylene group and a pentylene group.

Specific examples of the alkenylene group include an ethenylene group and a propenylene group. Among them, preferable examples include a propynylene group.

Specific examples of the cycloalkylene group include a cyclohexylene group and a cyclopentylene group. Among them, preferable examples include a cyclohexylene group.

Specific examples of the arylene group include a phenylene group and a naphthylene group. Among them, preferable examples include a phenylene group.

These linking groups may further have substituents. Examples of the substituent include a hydroxy group, an amino group, a sulfonyl group, a carboxyl group, a heterocyclic group, a pyridinium group, an aminoalkyl group, a phosphate group, an imino group, a thiol group, a sulfo group, and a nitro group.

Specific examples (exemplary compounds (A1) to (A46)) of the quaternary ammonium cation which can be used in the invention (specific cation) are listed below, while the invention is not limited to them.

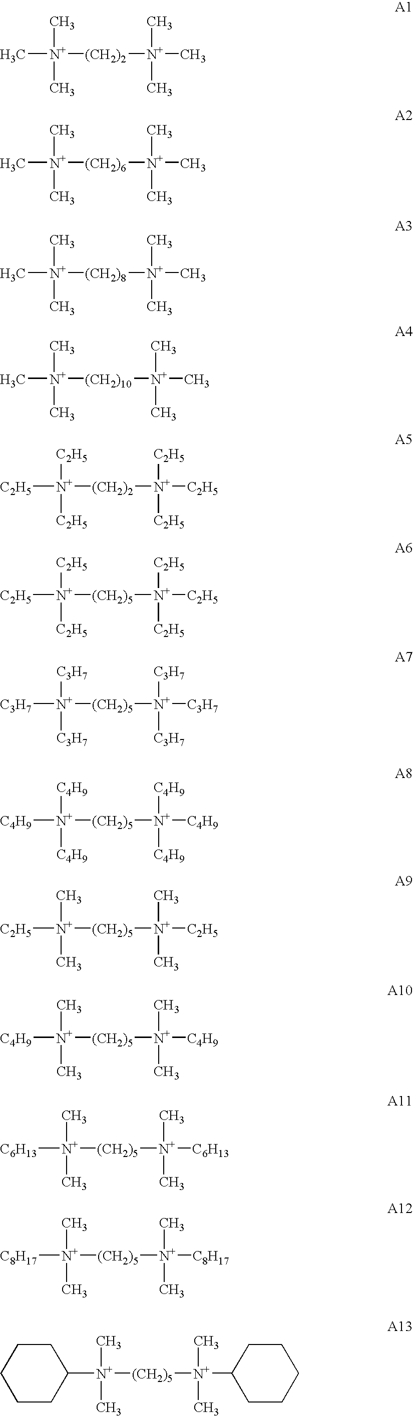

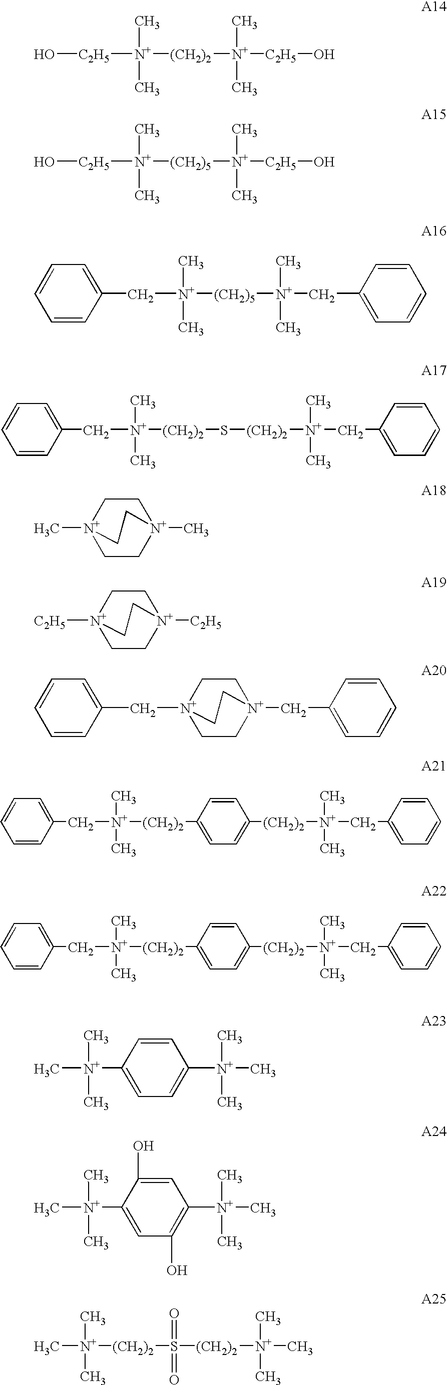

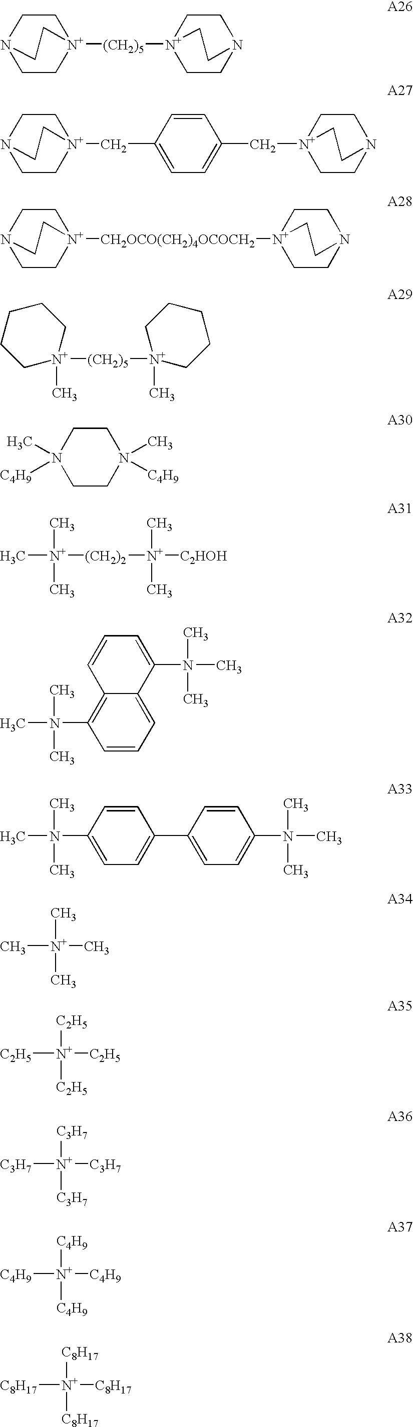

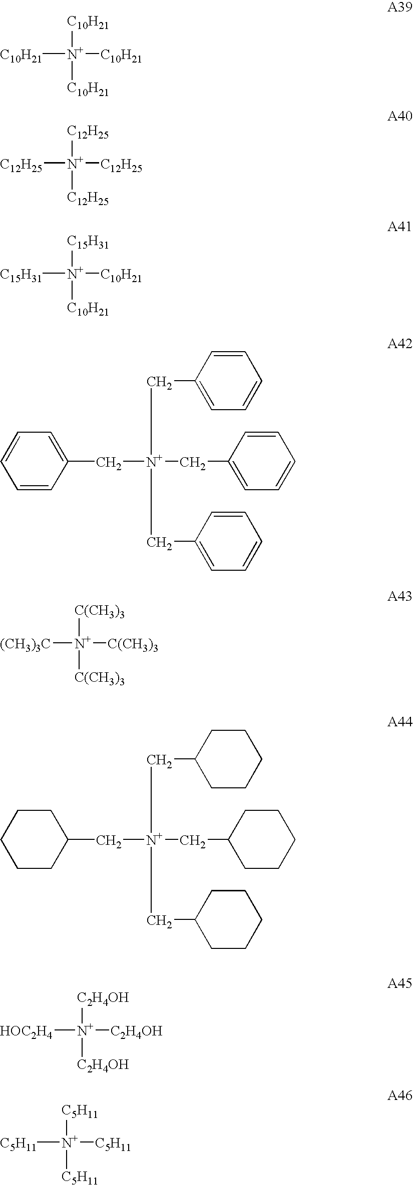

Among the specific examples of the quaternary ammonium cation (specific cation) (D), preferable examples thereof include A2, A8, A12, A16, A21, A22, A36, A37, and A46 from the viewpoint of dispersion stability in a polishing liquid.

The quaternary ammonium cation (D) (specific cation) may be synthesized by substitution reaction in which ammonia or an amine serves as a nucleophilic agent.

The specific cation may be commercially available as a generally-sold reagent.

The amount of the quaternary ammonium cation (D) (specific cation) is preferably in a range of 0.0001% by mass to 1% by mass, and is more preferably in a range of 0.0001% by mass to 0.3% by mass with respect to the total amount of the polishing liquid used for polishing (more specifically, polishing liquid after dilution with water or an aqueous solution, which may be also called as “polishing liquid used for polishing” herein). More specifically, the amount of the specific cation of 0.0001% by mass or more may be preferable for sufficiently improving the polishing rate, and the amount of the specific cation of 1% by mass or less may be preferable for achieving sufficient stability of the slurry.

The quaternary ammonium cation (D) (specific cation) according to the invention may be used singly, or in combination of two or more thereof.

Surfactant (E) (Anionic or Cationic Surfactant)

The polishing liquid of the invention preferably contains a surfactant (E) which may be either anionic or cationic.

Specific examples of the anionic surfactant include decylbenzenesulfonic acid, dodecylbenzenesulfonic acid, tetradecylbenzenesulfonic acid, hexadecylbenzenesulfonic acid, dodecylnaphthalenesulfonic acid, and tetradecylnaphthalenesulfonic acid.

Specific examples of the cationic surfactant include lauryl trimethyl ammonium, lauryl triethyl ammonium, stearyl trimethyl ammonium, palmityl trimethyl ammonium, octyl trimethyl ammonium, dodecyl pyridinium, decyl pyridinium, and octyl pyridinium.

In addition to the sulfonates, preferable examples of the anionic surfactant which may used in the invention further include carboxylates, sulfates, and phosphates.

Specific examples of the carboxylates include soap, N-acylamino acid salt, polyoxyethylene alkyl ether carboxylate, polyoxypropylene alkyl ether carboxylate, and acylated peptide. Specific examples of the sulfates include sulfated oil, alkyl sulfate, alkyl ether sulfate, polyoxyethylene alkyl allyl ether sulfate, polyoxypropylene alkyl allyl ether sulfate, and alkylamide sulfate.

Specific examples of the phosphates include alkyl phosphate, and polyoxyethylene alkyl allyl ether phosphate, and polyoxypropylene alkyl allyl ether phosphate.

The total amount of the surfactant (E) in the polishing liquid used for polishing is preferably in a range of 0.001 to 10 g, more preferably in a range of 0.01 to 5 g, and is particularly preferably in a range of 0.01 to 1 g with respect to 1 L of the polishing. More specifically, the total amount of the surfactant may be preferably from 0.01 g or more for achieving sufficient effect, and may be preferably 1 g or less for preventing the reduction of the CMP rate.

These surfactants may be used singly, or in combination of two or more thereof.

Other Components

In addition to the essential components (A) to (C) and preferable auxiliary components (D) and (E), the polishing liquid of the invention may further contain other known components as long as the addition of such other known components do not impair the effect of the invention.

pH Controlling Agent

The pH of the polishing liquid of the invention is preferably from 2 to 10, more preferably from 2 to 6, and is even more preferably from 2 to 5. When the pH of the polishing liquid is within the range, the polishing rate for the insulating layer can be more precisely controlled.

In order to adjust the pH to fall within the preferable range, an alkali or a buffering agent may be used in addition to the acid.

Preferable examples of the alkali or the buffering agent include nonmetal alkaline chemicals such as ammonia, ammonium hydroxide, organic ammonium hydroxides such as tetramethyl ammonium hydroxide, alkanolamines such as diethanolamine, triethanolamine or triisopropanolamine, and alkali metal hydroxides such as sodium hydroxide, potassium hydroxide, or lithium hydroxide.

Particularly preferable examples of the alkaline chemicals include ammonium hydroxide, potassium hydroxide, lithium hydroxide, and tetramethyl ammonium hydroxide.

The amount of the alkali or the buffering agent in the polishing liquid may be arbitrarily selected as long as the pH of the polishing liquid can be maintained within a preferable range. The amount is preferably from 0.0001 mol to 1.0 mol, and more preferably 0.003 mol to 0.5 mol in 1 L of the polishing liquid used for polishing.

Chelating Agent

The polishing liquid of the invention may preferably contain a chelating agent (more specifically, a water softener) in accordance with necessity in view of reducing deleterious effects by contaminants such as polyvalent metal ions.

Examples of the chelating agent include widely-used water softeners which prevent precipitation of calcium or magnesium and modified compounds thereof. Specific examples thereof include nitrilotriacetate, diethylenetriamine pentaacetate, ethylenediamine tetraacetate, N,N,N-trimethylenephosphonic acid, ethylenediamine-N,N,N′,N′-tetramethylenesulfonic acid, trans-cyclohexanediamine tetraacetate, 1,2-diaminopropane tetraacetate, glycoletherdiamine tetraacetate, ethylenediamine orthohydroxyphenyl acetic acid, ethylenediamine disuccinic acid (SS form), N-(2-carboxylate ethyl)-L-asparatic acid, β-alaninediacetic acid, 2-phosphonobutane-1,2,4-tricarboxylic acid, 1-hydroxyethylidene-1,1-diphosphonic acid, N,N′-bis(2-hydroxybenzyl)ethylenediamine-N,N′-diacetic acid, and 1,2-dihydroxybenzene-4,6-disulfonate.

The chelating agent may be used in combination of two or more thereof as necessary.

The chelating agent can be added to the polishing liquid of the invention in an amount enough to sequester metal ion contaminants such as polyvalent metal ions. For example, the amount of the chelating agent contained in 1 L of the polishing liquid used for polishing may be from 0.0003 mol to 0.07 mol.

Oxidant

The polishing liquid of the invention may contain a compound (oxidant) for oxidizing the metal to be polished.

Examples of the oxidant include hydrogen peroxide, peroxides, nitrates, iodates, periodates, hypochlorites, chlorites, chlorates, perchlorates, persulfates, dichromates, permanganates, ozone water, silver (II) salts, and iron (III) salts.

Preferable examples of iron (III) salts include inorganic iron (III) salts such as ferric nitrate (III), iron chloride (III), iron sulfate (III), or iron bromide (III), and organic complex salts of iron (III).

When an organic complex salt of iron (III) is used, examples of the compound forming the iron (III) complex salt include acetic acid, citric acid, oxalic acid, salicylic acid, diethyl dithiocarbamic acid, succinic acid, tartaric acid, glycolic acid, glycine, alanine, asparatic acid, thioglycollic acid, ethylenediamine, trimethylenediamine, diethylene glycol, triethylene glycol, 1,2-ethanedithiol, malonic acid, glutaric acid, 3-hydroxybutyric acid, propionic acid, phthalic acid, isophthalic acid, 3-hydroxysalicylic acid, 3,5-dihydroxy salicylic acid, gallic acid, benzoic acid, maleic acid, salts thereof, and aminopolycarboxylic acid and salts thereof.

Examples of aminopolycarboxylic acid and salts thereof include ethylenediamine-N,N,N′,N′-tetraacetate, diethylenetriamine pentaacetate, 1,3-diaminopropane-N,N,N′,N′-tetraacetate, 1,2-diaminopropane-N,N,N′,N′-tetraacetate, ethylenediamine-N,N′-disuccinic acid (racemic form), ethylenediamine disuccinic acid (SS form), N-(2-carboxylateethyl)-L-asparatic acid, N-(carboxymethyl)-L-asparatic acid, β-alaninediacetic acid, methyliminodiacetic acid, nitrilo triacetate, cyclohexanediamine tetraacetate, iminodiacetic acid, glycol ether diamine tetraacetate, ethylenediamine 1-N,N′-diacetate, ethylenediamine orthohydroxyphenylacetic acid, N,N-bis(2-hydroxybenzyl)ethylenediamine-N,N-diacetic acid, and salts thereof. Preferable examples of the salts of these include an alkali metal salt and an ammonium salt, and particularly preferable examples thereof an ammonium salt.

Among these oxidants, hydrogen peroxide, iodates, hypochlorites, chlorates, persulfates, and organic complex salts of iron (III) are preferable. When an organic complex salt of iron (III) is used, preferable examples of the compound forming the complex include citric acid, tartaric acid, and aminopolycarboxylic acids such as ethylenediamine-N,N,N′,N′-tetraacetate, diethylenetriamine pentaaceate, 1,3-diaminopropane-N,N,N′,N′-tetraacetate, ethylenediamine-N,N′-disuccinic acid (racemic form), ethylenediamine disuccinic acid (SS form), N-(2-carboxylate ethyl)-L-asparatic acid, N-(carboxymethyl)-L-asparatic acid, β-alaninediacetic acid, methyliminodiacetic acid, nitrilo triacetate, or iminodiacetic acid.

Particularly preferable examples of the oxidant include hydrogen peroxide, persulfates, and iron (III) complexes such as ethylenediamine-N,N,N′,N′-tetraacetate, 1,3-diaminopropane-N,N,N′,N′-tetraacetate, and ethylenediamine disuccinic acid (SS isomer).

The oxidant is preferably mixed with a composition containing components other than the oxidant to just before making the polishing liquid used for polishing. The oxidant is mixed preferably within 1 hour, and more preferably 5 minutes immediately before the use of the polishing liquid. Particularly preferably, the polishing apparatus is provided with a mixer which provides the oxidant to the polishing liquid feeding unit, and thereby the oxidant is mixed with the polishing liquid within 5 seconds immediately before the solution is fed to the surface to be polished.

When the wiring material should not be excessively polished in the barrier metal CMP, it is desirable to reduce the loading amount of the oxidant. When the degree of dishing is sufficiently small, and the wiring material is desired to be polished at a high speed, it is desirable to increase the loading amount of the oxidant.

In this way, the oxidant content is preferably changed according to the dishing condition in the initial stage of the barrier metal CMP. The oxidant content in 1 L of the polishing liquid used for polishing is preferably from 0.01 mol to 1 mol, and is particularly preferably from 0.05 mol to 0.6 mol.

Application of Polishing Liquid

The polishing liquid of the invention is capable of rapidly polishing a layer formed on a semiconductor integrated circuit, in particular a barrier layer. Therefore, the polishing liquid is particularly suitable for polishing of a barrier layer. The polishing liquid of the invention is also suitable for polishing of an insulating layer underlying the barrier layer.

Accordingly, the polishing liquid of the invention is suitable for polishing both of a barrier layer and an insulating layer by CMP at one step.

Barrier Metal Material

In general, the material composing the barrier layer is preferably a low-resistance metal material. Preferable examples of the material include TiN, TiW, Ta, TaN, W, WN, and Ru. More preferable examples among them include Ta and TaN. The polishing liquid of the invention is suitable for the barrier layers composed of these Ta-containing metal materials, and Mn, Ti, Ru, or compounds having any one thereof.

Insulating Layer

Examples of the insulating layer to be polished by the polishing liquid of the invention include common insulating layers such as a TEOS layer, and insulating layers containing a low-dielectric material having a low relative dielectric constant of about 3.5 to 2.0 (such as organic polymer, SiOC materials, or SiOF materials, a layer formed of which being usually abbreviated as a “Low-k film”).

Specific examples of the material used for forming a low-dielectric insulating layer include HSG-R7 (trade name, manufactured by Hitachi Chemical Co., Ltd.), BLACK DIAMOND (trade name, manufactured by Applied Materials, Inc), SILK (trade name, manufactured by The Dow Chemical Co), AURORA trade name, manufactured by ASM Japan K.K.), and CORAL (trade name, manufactured by Novellus Systems, Inc).

The Low-k film is usually underlies a TEOS insulating film. A barrier layer and a metal wiring are formed on the TEOS insulating film.

Wiring Metal Material

An object to be polished by the polishing liquid of the invention preferably has wiring containing at least a copper metal and/or a copper alloy commonly used for a semiconductor integrated circuit such as LSI. Particularly preferable examples of the material of the wiring include a copper alloy. Even more preferable examples of the material include a silver-containing copper alloy.

The silver content with respect to the total amount of the copper alloy is preferably 40% by mass or less, particularly preferably 10% by mass or less, and is more preferably 1% by mass or less. The copper alloy likely achieves the highest effect when the silver content thereof is from 0.00001 to 0.1% by mass.

Width of Wiring

In cases where an object to be polished by the polishing liquid of the invention is to be used for a DRAM device system or the like after being polished, the width of the wiring on the object is preferably set so that a half pitch of the wiring is 0.15 μm or less, more preferably 0.10 μm or less, and is even more preferably 0.08 m or less.

On the other hand, in cases where an object to be polished by the polishing liquid of the invention is to be used for a MPU device system or the like after being polished, the width of the wiring on the object is preferably 0.12 μm or less, more preferably 0.09 μm or less, and is even more preferably 0.07 μm or less.

The polishing liquid of the invention achieves particularly excellent effect on objects with wiring having the above-described thicknesses.

Polishing Method

Examples of the embodiments of the state of the polishing liquid of the invention include: (1) a concentrate which is diluted with water or an aqueous solution before use to prepare a working solution; (2) aqueous solutions of ingredients, which are mixed and may be diluted with water as necessary to make a working solution; and (3) a ready-to-use working solution.

The polishing method using the polishing liquid of the invention may employ any of these embodiments.

The polishing method includes: feeding the polishing liquid to a polishing pad on a polishing platen; contacting the polishing pad with a surface of an object to be polished; and moving the surface to be polished and the polishing pad relative to each other.

The apparatus used for polishing may be a common polishing apparatus having a holder for holding an object having a surface to be polished (for example, a wafer having a conductive material film), and a polishing platen equipped with a polishing pad and a rotation rate-variable motor or the like. There is no particular limitation to the polishing pad, and examples thereof include a common nonwoven fabric, foamed polyurethane, and a porous fluorocarbon resin.

There is no particular limitation to the polishing conditions. The rotation rate of the polishing platen is preferably 200 rpm or less so as to prevent the object from jumping out of the apparatus. The pressure applied from the object having the surface to be polished (film to be polished) to the polishing pad is preferably from 0.68 KPa to 34.5 KPa, and is more preferably from 3.40 KPa to 20.7 KPa from the viewpoints of satisfying uniformity of the polishing rate within the surface of the object and flatness of the pattern.

During polishing, the polishing liquid may be continuously fed to the polishing pad using a pump or the like. After completion of the polishing, the object may be thoroughly washed in running water, water droplets remaining on the object may be shaken off using a spin dryer or the like, and then the object may be dried.

When the concentrate of the polishing liquid of the invention is diluted as described in the embodiment (1), the aqueous solution used for diluting the concentrate may contain at least one or more of the benzotriazole compound (A) according to the invention, the acid (B), and the water-soluble polymer (C), so that the sum of the components of the concentrate to be diluted and the components of the aqueous solution for diluting the concentrate can be the components of the polishing liquid (working solution) used for polishing.

When a concentrate is diluted with the aqueous solution as described above, a component which hardly dissolves to the concentrate can be added in a form of an aqueous solution, which allows to make the concentrate thicker.

Examples of the method for diluting the concentrate with water or the aqueous solution include a method having at least: mixing a concentrated polishing liquid with water or the aqueous solution by jointing a pipe for feeding the concentrated polishing liquid with a pipe for feeding water or the aqueous solution and feeding these so as to be mixed; and feeding the resulted diluted polishing liquid to a polishing pad.

Examples of the method for mixing the concentrate with water or the aqueous solution include common methods such as a method of colliding and mixing the liquids by passing them though narrow passages under pressure, a method of repeatedly dividing and joining streams of the liquids by passing them through the pipe packed with glass tubes or the like, and a method of providing power-driven blades in the pipe.

The rate of feeding of the polishing liquid is preferably from 10 to 1000 ml/min, and is more preferably from 170 to 800 ml/min from the viewpoints of satisfying uniformity of the polishing rate within one plane of the surface of the object and flatness of the pattern.

Examples of the method for conducting polishing while diluting the concentrate with water or the aqueous solution further include a method having at least providing a pipe which is for feeding the polishing liquid and a pipe which is for feeding water or an aqueous solution and is independent from the pipe for feeding the polishing liquid, feeding predetermined amounts of the liquids from the respective pipes to a polishing pad, and conducting polishing while mixing the liquids by moving the pad and the surface to be polished relative to each other. Examples of the polishing method include a method having at least mixing predetermined amounts of the concentrate and water or the aqueous solution in one container, feeding the mixed polishing liquid to a polishing pad, and conducting polishing.

Examples of the polishing method further include a method having at least dividing the ingredients of the polishing liquid into two or more ingredient groups, diluting each of the two or more ingredient groups with water or the aqueous solution, feeding the resulted diluted liquids to a polishing pad on a polishing platen, contacting the polishing pad with the surface to be polished, and moving the surface to be polished and the polishing pad relative to each other.

For example, the benzotriazole compound according to the invention is used as a component group (A), and an acid, other additives, and water are used as a component group (B), and the component groups (A) and (B) are diluted with water or the aqueous solution and used for polishing.

Alternatively, poorly soluble additives may be divided into two component groups (A) and (B), and the component groups may be diluted with water or the aqueous solution upon being used.

Three pipes, which includes a pipe for feeding the component group (A), a pipe for feeding the component group (B), and a pipe for feeding water or the aqueous solution, are required in the above examples. The dilution and mixing method may be conducted by using a system formed by jointing the three pipes to one pipe which feeds the component groups and the water or the aqueous solution to a polishing pad, and mixing the liquids in the pipe. In this case, a system in which two pipes among the three pipes are jointed first, and then other one pipe is jointed thereto may be used. Specific examples of such dilution and mixing method include a method using a system formed by firstly jointing a pipe for feeding a component group containing poorly soluble additives to a pipe for feeding a component group containing other ingredients so as to elongate the mixing time of these component groups so as to obtain enough time length to dissolve these component groups with each other and then jointing thereto a pipe for feeding water or the aqueous solution.

Examples of the mixing method further include a method having using a system having the three pipes which respectively directly introduce the liquids to a polishing pad and moving the polishing pad and the surface to be polished relative to each other as described above, and a method having mixing the three liquids in one container by using a system having the three pipes which introduce the liquids to the container and then feeding the resulted diluted polishing liquid to a polishing pad.

In one embodiment of the polishing method, a temperature of one component group is set at 40° C. or lower, and a temperature of another component group is heated so as to be in a range from room temperature to 100° C., while liquid temperature resulted by mixing the component groups or by diluting the component groups with water or the aqueous solution is set to be 40° C. or lower. This embodiment utilizes the phenomenon that solubility of a material increases as the increase of a temperature of a system to solve the material, and is suitable for increasing solubility of poorly soluble ingredients which may be contained in the polishing liquid.

The poorly soluble ingredients dissolved in the component group by heating to be in a range from room temperature to 100° C. may be precipitated in the solution if the temperature of the component group is lowered. Therefore, when the component group which is at a low temperature and contains such precipitated poorly soluble ingredients is subjected to the mixing with other liquid for diluting, it is needed to heat the component group before the mixing so as to dissolve the precipitated ingredients. This may be done by a method having heating to dissolve the ingredients to the component group and then feeding the solution, or may be a method having stirring the liquid of the component group containing the precipitate, and conducting feeding of the liquid through the pipe while heating the pipe so as to dissolving the precipitate. When a temperature of one component group containing an oxidant is raised to 40° C. or higher by the heated component group, the oxidant may be decomposed. Therefore, when the component group containing an oxidant is mixed with the heated component group, the temperature of the mixture resulted therefrom is preferably 40° C. or lower.

As described above, in the invention, the ingredients of the polishing liquid may be divided into two or more component groups and fed to the surface to be polished by respectively feeding the two or more groups. In this case, it is preferable that the ingredients are divided so that a component group containing an oxidant is different from another component group containing an organic acid. Alternatively, the polishing liquid may be fed to a surface to be polished as a concentrate, which is diluted with water which is also fed to the surface to be polished.

In the invention, when the components of the polishing liquid are divided into two or more component groups and fed to the surface to be polished, the amount of the polishing liquid supplied to a surface to be polished is the total amount of the liquids supplied from the respective pipes to the surface to be polished.

Pad

The polishing pad which may be used in the polishing method of the invention may be either a nonfoamed pad or a foamed pad. The nonfoamed pad is composed of a synthetic hard resin bulk matter such as a plastic board. Examples of the foamed pad include closed-cell foam-containing matters (dry foam-containing matters), open-cell foam-containing matters (wet foam-containing matters), and two-layer composites (laminate matters). Among them, two-layer composites (laminate matters) are preferable. Cells in a foamed pad may be either uniform or nonuniform.

The pad may contain abrasive grains (such as ceria, silica, alumina, or resins) which are commonly used for polishing, while it is preferable that the pad contains no abrasive grain. In cases where the pad contains abrasive grains, the abrasive grains may be either soft or hard. In cases where the pad is a laminate containing abrasive grains, it is preferable that the hardnesses of the abrasive grains contained in respective layers of the laminate are different from each other. Preferable examples of the material of the abrasive grains include nonwoven fabrics, artificial leathers, polyamide, polyurethane, polyester, and polycarbonate. A surface side of the pad which contacts with a surface to be polished may be subjected to processing to be provided with a lattice trench, a hole, a homocentric trench, and/or a helical groove.

Wafer

A wafer, which can be the object of CMP using the polishing liquid of the invention, preferably has a diameter of 200 mm or more, and more preferably has a diameter of 300 mm or more. The effect of the invention is particularly remarkable when the wafer diameter is 300 mm or more.

Polishing Apparatus

The apparatus for polishing using the polishing liquid of the invention is not particularly limited. Examples of the apparatus include MIRRA MESA CMP and REFLEXION CMP (both trade names, manufactured by Applied Material, Inc.), FREX 200 and FREX 300(both trade names, manufactured by Ebara Corporation), NPS 3301 and NPS 2301 (both trade names, manufactured by Nikon Corporation), A-FP-310A and A-FP-310A (both trade names, manufactured by Tokyo Seimitsu Co., Ltd.), 2300 TERES (trade name, manufactured by Lam Research Co., Ltd.), and MOMENTUM (trade name, manufacture by Speedfam IPEC).

### EXAMPLES

Hereinafter, the polishing liquid of the present invention is specifically described with reference to Examples, while the Examples should not be construed as limiting the invention.

### Example 1

A polishing liquid having the following formulation (1) was prepared, and subjected to polishing test.

Formulation (1):

(A) BTA compound A-5 (benzotriazole compound) 1.0 g/L

(B) Glycolic acid (acid) 0.5 g/L

(C) Polyacrylate-polymethacrylate copolymer (water-soluble polymer) 0.5 g/L

Pure water Remainder to make 1000 mL

The pH of the polishing liquid was adjusted to be 3.0 by using ammonia water and nitric acid.

Evaluation

### Conditions for Polishing

A polishing apparatus “LGP-612” (trade name, manufactured by Lapmaster SFT Corp.) was used. The films formed on the respective wafers were polished while being provided with a slurry under the following polishing conditions, and the polishing rates were calculated.

Table rotation speed: 64 rpm

Head rotation speed: 65 rpm (working linear speed: 1.0 m/s)

Polishing pressure: 70 hPa

Polishing pad: IC-1400 (K-grv) (trade name, manufactured by Rohm and Haas)

Feeding rate of the polishing liquid: 200 ml/min

Object to be Polished Upon Evaluation of Polishing Rate

A 200 mm (8-inch) wafer was formed by providing, on a Si substrate (200 mm (8-inch) silicon wafer having a copper film), an object to be polished (a titanium barrier layer) and used for the evaluation.

Object to be Subjected to Scratch Preventing Property Evaluation

A 200 mm (8-inch) wafer was formed by providing, on a Si substrate (200 mm (8-inch) silicon wafer having a copper film), an object to be polished (Cu and porous-low-k film; k value: 2.4) and used for the evaluation.

Evaluation of Polishing Rate

The thickness of the titanium film (barrier layer) of the object to be polished (namely, a layer (film) thickness before polishing) and that of the object polished by CMP (namely, a layer (film) thickness after polishing) were measured, and the polishing rate was calculated from the following equation. The result thereof are listed in the following Table 1.

Polishing rate (nm/minute)=(layer (film) thickness before polishing−layer (film) thickness after polishing)/polishing time

Evaluation of Scratch Preventing Property

The wafer having the object to be polished was subjected to polishing for 10 seconds, washing, and drying, and scratches generated on the surface of the object after the treatments were observed using a surface scanning apparatus SP1 (trade name, manufactured by KLA-TENCOR Corporation). The results thereof are listed in Table 1. The evaluation criteria are as follows.

Criteria for Evaluation of Scratch Preventing Property

A: 5 or less scratches of 0.14 mm or more were observed on one wafer

B: More than 5 and less than 15 scratches of 0.14 mm or more were observed on one wafer

X: 15 or more scratches of 0.14 mm or more were observed on one wafer

### Examples 2 to 27 and Comparative Examples 1 to 3

Wafers having the objects to be evaluated for Examples 2 to 27 and Comparative Examples 1 to 3 were prepared, subjected to the polishing treatments, and evaluated in the same manner as Example 1 except that the formulation (1) of the polishing liquid used in Example 1 was changed to the formulations shown in the following Tables 1 and 2. The results are listed in Tables 1 and 2.

TABLE 1

| | Polishing | | | | | | | Scratch | |
|---|---|---|---|---|---|---|---|---|---|
| | particles | | | | | | Ti | preventing | |
| | (content, | BTA | | | Other | | polishing | property | |
| | particle | compound | | | component | | rate | | Low-k |
| | diameter) | (content) | Acid (content) | Water-soluble polymer (content) | (content) | pH | (nm/mm) | Cu | film |
| Example 1 | — | A-5 (1.0 g/L) | Glycolic acid (0.5 g/L) | Polyacrylate-polymethacrylate | — | 3.0 | 20 | A | A |
| | | | | copolymer (1.5 g/L) | | | | | |
| Example 2 | — | A-6 (1.0 g/L) | Oxalic acid (0.5 g/L) | Polyacrylic acid (M.W. 500000) | — | 2.5 | 6 | A | A |
| | | | | (0.5 g/L) | | | | | |
| Example 3 | — | A-7 (1.0 g/L) | Glycolic acid (0.5 g/L) | Polymaleic acid (M.W. 15000) | HMC (0.5 g/L) | 3.0 | 10 | A | A |
| | | | | (1.0 g/L) | | | | | |
| Example 4 | — | A-8 (1.0 g/L) | Malic acid (0.5 g/L) | Polyacrylamide (M.W. 10000) | DBSA (1.0 g/L) | 3.0 | 5 | A | A |
| | | | | (0.5 g/L) | | | | | |
| Example 5 | — | A-9 (1.0 g/L) | Citric acid (0.5 g/L) | Polymaleic acid (M.W. 15000) | — | 3.0 | 9 | A | A |
| | | | | (1.0 g/L) | | | | | |
| Example 6 | — | A-10 (1.0 g/L) | Glycolic acid (0.5 g/L) | Polyacrylate-polymethacrylate | — | 2.5 | 10 | A | A |
| | | | | copolymer (1.5 g/L) | | | | | |
| Example 7 | — | A-11 (1.0 g/L) | Malic acid (0.5 g/L) | Polyacrylate-polyacrylamide | — | 5.0 | 16 | A | A |
| | | | | copolymer (2.0 g/L) | | | | | |
| Example 8 | — | A-12 (1.0 g/L) | Citric acid (0.5 g/L) | Polyacrylate-polymethacrylate | TBAN (0.5 g/L) | 4.0 | 16 | A | A |
| | | | | copolymer (1.5 g/L) | | | | | |
| Example 9 | — | A-13 (1.0 g/L) | Citric acid (0.5 g/L) | Polyacrylic acid (M.W. 25000) | TMAN (0.5 g/L) | 3.0 | 11 | A | B |
| | | | | (1.0 g/L) | | | | | |
| Example 10 | — | A-14 (1.0 g/L) | Adipic acid (0.5 g/L) | Polymaleic acid (M.W. 15000) | — | 2.0 | 13 | A | A |
| | | | | (1.0 g/L) | | | | | |
| Example 11 | — | A-15 (1.0 g/L) | Succinic acid (0.5 g/L) | Polyacrylate-polymethacrylate | DPC (0.5 g/L) | 6.0 | 9 | A | A |
| | | | | copolymer (1.5 g/L) | | | | | |
| Example 12 | — | A-17 (1.0 g/L) | Malonic acid (0.5 g/L) | Polymaleic acid (M.W. 15000) | DBSA (1.0 g/L | 3.5 | 15 | A | A |
| | | | | (1.0 g/L) | | | | | |
| Example 13 | — | A-21 (1.0 g/L) | Glycolic acid (0.5 g/L) | Polymaleic acid (M.W. 15000) | — | 4.5 | 21 | A | A |
| | | | | (1.0 g/L) | | | | | |
| Example 14 | — | A-22 (1.0 g/L) | Malic acid (0.5 g/L) | Polyacrylate-polyacrylamide | — | 3.0 | 15 | A | A |
| | | | | copolymer (2.0 g/L) | | | | | |
| Example 15 | — | A-23 (1.0 g/L) | Glycolic acid (0.5 g/L) | Polyacrylamide (M.W. 10000) | — | 3.5 | 15 | A | A |
| | | | | (0.5 g/L) | | | | | |

TABLE 2

| | Polishing | | | | | | | Scratch | |
|---|---|---|---|---|---|---|---|---|---|
| | particles | | | | | | Ti | preventing | |
| | (content, | BTA | | | Other | | polishing | property | |
| | particle | compound | | | component | | rate | | low-k |
| | diameter) | (content) | Acid (content) | Water-soluble polymer (content) | (content) | pH | (nm/mm) | Cu | film |
| Example 16 | — | A-28 (1.0 g/L) | Malic acid (0.5 g/L) | Polyacrylate-polymethacrylate | — | 6.0 | 23 | A | B |
| | | | | copolymer (1.5 g/L) | | | | | |
| Example 17 | — | A-29 (1.0 g/L) | Oxalic acid (0.5 g/L) | Polyacrylic acid (M.W. 25000) | HMC (0.5 g/L) | 4.5 | 14 | A | A |
| | | | | (1.0 g/L) | | | | | |
| Example 18 | — | A-32 (1.0 g/L) | Oxalic acid (0.5 g/L) | Polyacrylamide (M.W. 10000) | DBSA (1.0 g/L) | 3.0 | 15 | A | A |
| | | | | (0.5 g/L) | | | | | |
| Example 19 | — | A-33 (1.0 g/L) | Adipic acid (0.5 g/L) | Polyacrylic acid (M.W. 25000) | HMC (0.5 g/L) | 5.0 | 5 | A | A |
| | | | | (1.0 g/L) | DBSA (1.0 g/L) | | | | |
| Example 20 | — | A-41 (1.0 g/L) | Glycolic acid (0.5 g/L) | Polyacrylate-polymethacrylate | TBAN (0.5 g/L) | 3.5 | 7 | A | A |
| | | | | copolymer (1.5 g/L) | | | | | |
| Example 21 | — | A-5 (0.7 g/L) | Tartaric acid (0.5 g/L) | Polyacrylic acid (M.W. 5000) | — | 3.0 | 14 | A | A |
| | | A-7 (0.3 g/L) | | (2.0 g/L) | | | | | |
| Example 22 | — | A-9 (1.0 g/L) | Glycolic acid (0.5 g/L) | Polyacrylamide (M.W. 10000) | DBSA (1.0 g/L) | 2.0 | 8 | A | A |
| | | A-17 (0.5 g/L) | | (0.5 g/L) | | | | | |
| Example 23 | — | A-5 (0.6 g/L) | Adipic acid (0.5 g/L) | Polyacrylic acid (M.W. 25000) | — | 3.0 | 7 | A | A |
| | | A-22 (0.4 g/L) | | (0.5 g/L) (1.0 g/L) | | | | | |
| Example 24 | — | A-7 (1.0/L) | Malic acid (0.5 g/L) | polymethacrylic acid | — | 3.0 | 6 | A | A |
| | | A-15 (1.0 g/L) | | (M.W 10000) (1.0 g/L) | | | | | |
| Example 25 | — | A-8 (0.7 g/L) | Tartaric acid (0.5 g/L) | Polymaleic acid (M.W. 25000) | DBSA (1.0 g/L) | 3.0 | 14 | A | A |
| | | A-23 (0.3 g/L) | | (1.0 g/L) | | | | | |
| Example 26 | — | A-10 (1.0 g/L) | Glycine (0.5 g/L) | Polyacrylate- | HMC (0.5 g/L) | 4.0 | 12 | A | A |
| | | A-33 (0.5/L | | polymethacrylamide copolymer | DBSA (1.0 gU) | | | | |
| | | | | (2.0 g/L) | | | | | |
| Example 27 | — | A-5 (0.6 g/L) | Glycine (0.5 g/L) | Polyacrylic acid (M.W 50000) | — | 3.5 | 11 | A | A |
| | | A-41 (0.47 | | (0.5 g/L) | | | | | |
| Comparative | S-1 | BTA (1.0 g/L) | Glycine (0.5 g/L) | — | — | 3.0 | 40 | B | C |
| example 1 | (100 g/L) | | | | | | | | |
| Comparative | S-1 | BTA (1.0 g/L) | Glycine (0.5 g/L) | Polyacrylic acid (M.W. 25000) | — | 7.0 | 35 | C | C |
| example 2 | (100 g/L) | | | (1.0 g/L) | | | | | |
| Comparative | S-7 | BTA (1.0 g/L) | Glycine (0.5 g/L) | — | DBSA (1.0 g/L) | 10.0 | 50 | C | C |
| example 3 | (150 g/L) | | | | | | | | |

The abbreviations in Tables 1 and 2 refer to the following compounds.

DBSA: dodecylbenzenesulfonic acid (surfactant)

TBAN: tetrabutyl ammonium nitrate (cationic quaternary ammonium salt)

HMC: hexamethonium chloride (cationic quaternary ammonium salt)

TMAN: tetrametyl ammonium nitrate (cationic quaternary ammonium salt)

DPC: dodecylpyridinium chloride (surfactant)

Details of the colloidal silica particles used in Comparative Examples are as follows.

S-1: colloidal silica (trade name: PL-3, manufactured by Fuso Chemical Co., Ltd., particle size: 35 nm, cocoon-shaped)

S-7: fumed silica, particle size: 30 nm

Tables 1 and 2 indicate that the polishing liquids of Examples 1 to 27 provide higher polishing rates for titanium and higher defect-preventing property (scratch preventing property) than that of the polishing liquids of Comparative Examples 1 to 3.

What is claimed is:

1. A polishing liquid used for chemical mechanical polishing during planarization of a semiconductor integrated circuit, the polishing liquid being substantially free of solid abrasive grains and comprising: a benzotriazole compound (A) represented by the following Formula (1); an acid (B); and a water-soluble polymer (C): 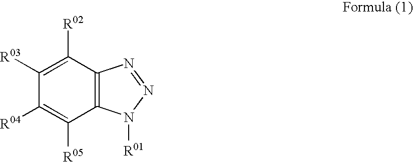
wherein each of R⁰¹ to R⁰⁵ independently represents a hydrogen atom or an alkyl group, and at least one of R⁰¹ to R⁰⁵ represents an alkyl group.

2. The polishing liquid of claim 1, further comprising a quaternary ammonium cation (D) having one or more quaternary nitrogen atoms in a molecule thereof.

3. The polishing liquid of claim 1, wherein the acid (B) comprises at least one selected from the group consisting of oxalic acid, glycolic acid, lactic acid, malonic acid, succinic acid, glutaric acid, adipic acid, maleic acid, malic acid, tartaric acid, citric acid, and modified compounds thereof.

4. The polishing liquid of claim 1, wherein the water-soluble polymer (C) comprises at least one selected from the group consisting of a polymer having a carboxylic monomer as a basic structural unit, a salt thereof, and a copolymer containing at least one of the polymer and the salt.

5. The polishing liquid of claim 4, wherein the polymer having a carboxylic monomer as a basic structural unit comprises at least one selected from the group consisting of a polyacrylic acid, a polymaleic acid, a polymethacrylic acid, and a polyacrylamide.

6. The polishing liquid of claim 1, the pH of which is in a range of 2 to 6.

7. The polishing liquid of claim 1, further comprising a surfactant (E) which is anionic or catiomc.

8. A polishing method for planarizing a semiconductor integrated circuit, the polishing method comprising chemically and mechanically polishing a barrier layer of the semiconductor integrated circuit using the polishing liquid of claim 1.

9. The polishing method of claim 8, wherein the barrier layer comprises at least one selected from the group consisting of Mn, Ti, Ru, and a compound comprising any one thereof.

10. The polishing method of claim 8, wherein the semiconductor integrated circuit comprises an insulating layer, and the polishing method further comprises chemically and mechanically polishing the insulating layer using the polishing liquid.
